(19) United States
(12) Patent Application Publication
(10) Pub. No.: US 2026/0113896 A1
(43) Pub. Date: Apr. 23, 2026

(54) MODULAR COOLING DISTRIBUTION SYSTEM

(71) Applicant: LTI Holdings Inc., Pleasanton, CA (US)

(72) Inventors: Steven J. Medeiros, Loudon, NH (US); Jeffrey A. Henning, Exeter, NH (US)

(21) Appl. No.: 19/359,917

(22) Filed: Oct. 16, 2025

Related U.S. Application Data
(60) Provisional application No. 63/708,568, filed on Oct. 17, 2024.

(51) Int. Cl. H05K 7/20

(52) U.S. Cl. CPC H05K 7/20781

(57) ABSTRACT

A modular cooling distribution system includes a first cooling distribution unit (CDU), a second CDU, and a component to be cooled. The system may include a primary closed loop in fluid communication with the first CDU, the second CDU, and an external cooling structure and a secondary closed loop in fluid communication with the first CDU, the second CDU, and the component to be cooled. The first cooling distribution unit and the second cooling distribution unit are modularly coupleable to one another and modularly operable as a CDU group whereby either or both of the pumps of the first and second CDUs are configured to drive fluid in the secondary closed loop to pass heat of the component to the secondary closed loop, the primary closed loop, and the external cooling structure.

### CROSS-REFERENCE TO RELATED APPLICATIONS

This application claims priority to U.S. Provisional Application No. 63/708,568, filed Oct. 17, 2024, the entire contents of which are incorporated herein by reference.

### FIELD

The present disclosure generally relates to cooling distribution units for directing heat away from electrical components.

### BACKGROUND

Cooling distribution units (commonly referred to as CDU's) are often utilized in data centers to remove heat from computer components (e.g., servers and server racks). Cooling distribution units may include, for example, both in-row units and in-rack units. In-row units remove heat from an entire row of server racks or other sets of electrical components, while in-rack units typically remove heat from a single rack or set of electrical components.

### SUMMARY

In accordance with one example, a modular cooling distribution system includes a first cooling distribution unit including a first heat exchanger and a first pump positioned within a first housing; a second cooling distribution unit including a second heat exchanger and a second pump positioned within a second housing; a component to be cooled positioned within a third housing; a primary closed loop in fluid communication with the first heat exchanger, the second heat exchanger, and an external cooling structure; a secondary closed loop in fluid communication with the first heat exchanger, the second heat exchanger, and the component to be cooled; wherein the first cooling distribution unit and the second cooling distribution unit are modularly coupleable to one another and modularly operable as a cooling distribution unit group whereby either or both of the first pump and the second pump are configured to drive fluid in the secondary closed loop to pass heat of the component to the secondary closed loop, the primary closed loop, and the external cooling structure.

In accordance with another example, a modular cooling distribution system includes a housing including a first receptacle configured to removably receive a first sub-housing and a second receptacle configured to removably receive a second sub-housing; a first cooling distribution unit including a first heat exchanger and a first pump, the first cooling distribution unit positioned within the first sub-housing; a second cooling distribution unit including a second heat exchanger and a second pump, the second cooling distribution unit positioned with the second sub-housing; and a component to be cooled; a primary closed loop in fluid communication with the first heat exchanger, the second heat exchanger, and an external cooling structure; and a secondary closed loop in fluid communication with the first heat exchanger, the second heat exchanger, and the component to be cooled.

In accordance with another example, a modular cooling distribution system includes a row of a plurality of housings each including a plurality of racks with an electrical component to be cooled; a first cooling distribution unit including a first heat exchanger and a first pump; a second cooling distribution unit including a second heat exchanger and a second pump; a primary closed loop in fluid communication with the first heat exchanger, the second heat exchanger, and an external cooling structure; a secondary closed loop in fluid communication with the first heat exchanger, the second heat exchanger, and the plurality of components to be cooled; wherein the first cooling distribution unit and the second cooling distribution are modularly coupled to the primary closed loop and the secondary closed loop so to be rearrangeable in the row or to a receptacle in at least one of the plurality of racks.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic view of a cooling distribution unit in accordance with one example.

FIG. 2 is a perspective view of the cooling distribution unit of FIG. 1.

FIG. 3 is another perspective view of the cooling distribution unit of FIG. 1.

FIG. 4 is another perspective view of the cooling distribution unit of FIG. 1

FIG. 5 is a schematic view of a cooling distribution system including an end-of-row cooling distribution group with a first cooling distribution unit and an adjacent second cooling distribution unit.

FIG. 6 is a schematic view of a cooling distribution system including a cooling distribution group with a first end-of-row first cooling distribution unit and an opposite second end-of-row second cooling distribution unit.

FIG. 7 is a schematic view of a cooling distribution system including a cooling distribution group with an in-row first cooling distribution unit and an in-row second cooling distribution unit interspersed with working row housings.

FIG. 8 is a schematic view of a cooling distribution system including a housing with stacked first and second receptacles.

### DETAILED DESCRIPTION

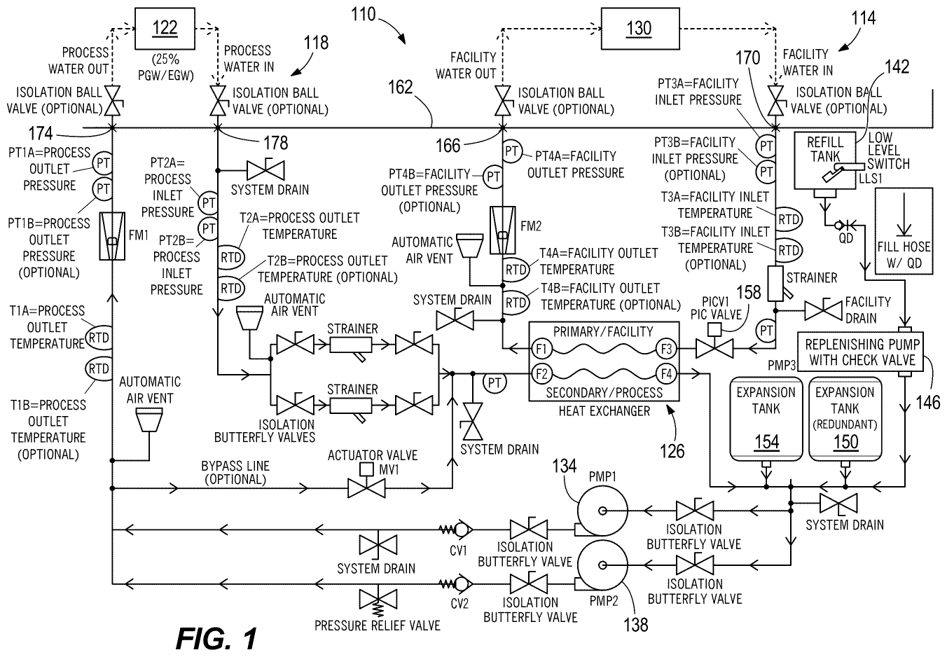

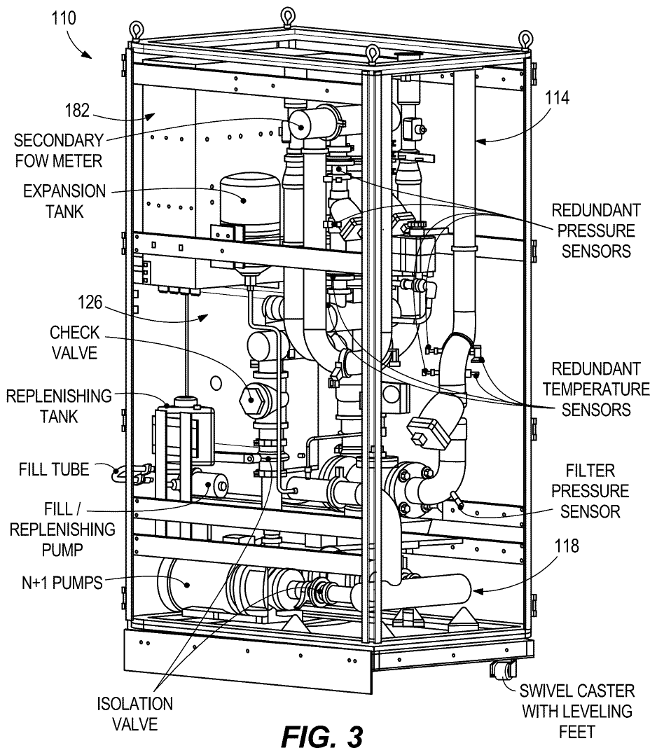

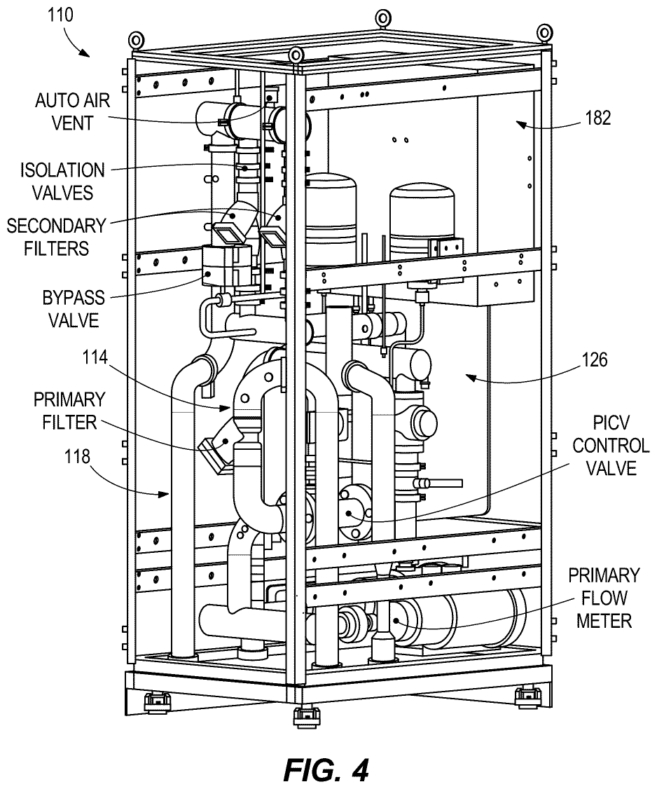

FIGS. 1-4 illustrate an example of a cooling distribution unit 110. The cooling distribution unit 110 may be used in any of a variety of settings, including for example in a server, data center, medical, semiconductor, and/or industrial application. The illustrated cooling distribution unit 110 is an in-row unit, although any of the concepts described herein related to the cooling distribution unit 110 may alternatively be used with an in-rack unit, or with any other type of cooling distribution unit.

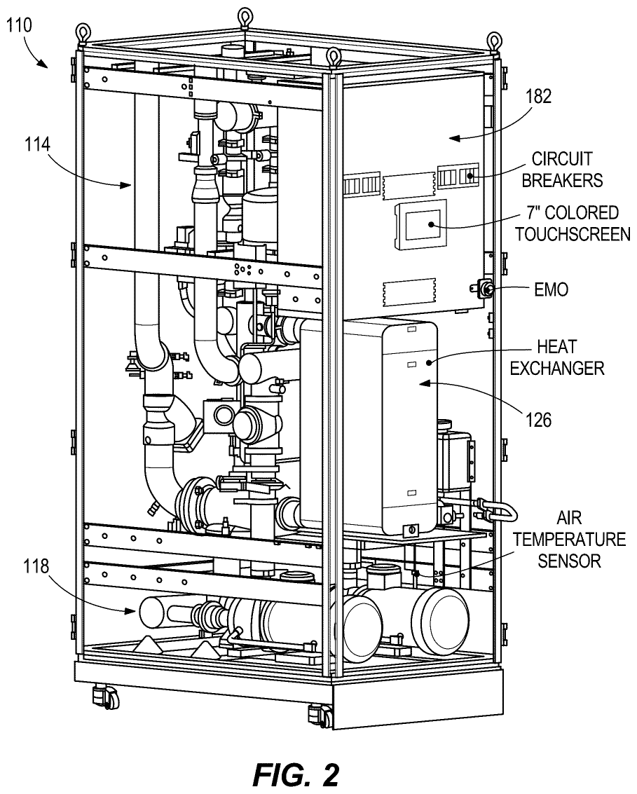

With reference to FIG. 1, the cooling distribution unit 110 generally includes a primary closed loop 114 and a secondary closed loop 118. The primary closed loop 114 circulates a first fluid (e.g., facility water located and/or otherwise supplied at a data server center). The secondary closed loop 118 circulates a second fluid (e.g., a process water solution that includes 25% propylene glycol and 75% water). Other examples include different first and second fluids within either of the primary closed loop 114 or the secondary closed loop 118. As illustrated in FIGS. 2-4, the primary closed loop 114 includes piping (e.g., stainless steel piping) through which the first fluid circulates. The secondary closed loop 118 similarly includes piping (e.g., stainless steel piping) through which the second fluid circulates. Other examples include other types of piping, including piping made of other materials, or having other shapes and configurations than that illustrated.

In some examples, the first fluid may be composed of or include water or propylene glycol-water solutions having a 50% maximum concentration. In other words, the concentration of the glycol-water solution may have a maximum concentration of 10 mg/L. The second fluid may be composed of or include water or a premixed solution of uninhibited ethylene-glycol or propylene-glycol and water. The first fluid and the second fluid may have a largest particle size of less than 200 microns. Other examples may include other materials and/or compositions of materials and/or particle sizes for the first fluid and/or the second fluid.

With continued reference to FIG. 1, the secondary closed loop 118 circulates the second fluid through and/or across one or more electrical components 122, to pick up heat from the electrical components 122. The electrical components 122 may include, for example, computer chips or other heated electrical components in one or more servers or server racks. In some examples, cold plates or other thermal devices may be positioned over the computer chips, and the piping of the secondary closed loop may pass through the cold plates or other thermal devices to pick up the heat from the electrical components 122. Once the second fluid in the secondary closed loop 118 has been heated by the electrical components 122, the heated second fluid is directed to a heat exchanger 126.

With continued reference to FIG. 1, each of the primary closed loop 114 and the secondary closed loop 118 extends through the heat exchanger 126. In the illustrated example, the heat exchanger 126 is a liquid-to-liquid heat exchanger. The primary closed loop 114 directs the first fluid in a first direction (e.g., to the left as viewed in FIG. 1) through the heat exchanger 126, and the secondary closed loop 118 directs the second fluid in a second direction (e.g., to the right as viewed in FIG. 1) through the heat exchanger 126. In the illustrated example, the first direction is parallel to, and opposite, the first direction. In other examples the first fluid and the second fluid may be directed in the same direction, or in a transverse direction, or the first and second fluids may be moved in more than one direction in the heat exchanger 126.

Within the heat exchanger 126, heat is exchanged between the second fluid and the first fluid. Accordingly, at least a portion of the heat picked up from the electrical components 122 is transferred from the second fluid to the first fluid within the heat exchanger 126. In some examples, the piping of the primary closed loop 114 does not contact the piping of the secondary closed loop 118 within the heat exchanger 126, and the heat is exchanged through an intermediary material (e.g., through a thermally conductive material). Other examples may include various other types or number or arrangements of heat exchangers 126 than that illustrated.

With continued reference to FIG. 1, the primary closed loop 114 directs the first fluid (after having been heated in the heat exchanger 126) away from the heat exchanger 126, and to a cooling structure 130 (e.g., external cooling structure). The cooling structure 130 may be located for example within a data server center. The cooling structure 130 may be any of a variety of different structures, including a cooling tower or other thermal device that sheds or otherwise removes heat from the first fluid. In some examples, the cooling structure 130 may include a cold plate, fins, and/or other structures that remove heat, and/or may use a fan or fans to facilitate removal of heat from the first fluid.

As illustrated in FIG. 1, once the heat has been removed from the first fluid at the cooling structure 130, the first fluid is then circulated back toward the heat exchanger 126. Similarly, once the heat has been removed from the second fluid at the heat exchanger 126, the second fluid is circulated back toward the electrical components 122. This circulation through each of the primary closed loop 114 and the secondary closed loop 118 may continue (e.g., for as long as the electrical components 122 are generating heat), such that heat is continuously picked up from the electrical components and delivered to the heat exchanger 126, where the heat is then transferred to the first fluid and the primary closed loop 114, and eventually discarded at the cooling structure 130.

With continued reference to FIG. 1, each of the primary closed loop 114 and the secondary closed loop 118 may include one or more pumps to pump the first fluid and the second fluid through the piping. In the illustrated example, the primary closed loop 114 includes one or more pumps (not illustrated) located within the data server center (e.g., at the location of the cooling structure 130, or elsewhere within the data server center, to pump the first fluid (e.g., facility water) through the primary closed loop 114. The secondary closed loop 118 includes both a first pump 134 and a second pump 138. The first and second pumps 134, 138 are redundant pumps, positioned along parallel lines within the closed loop, such that if one of the pumps fails, the other may continue to operate the overall flow of the second fluid within the secondary closed loop 118. The first pump 134 and the second pump 138 may be any type of pump that can pump the second fluid. In some examples, the first pump 134 and the second pump 138 are identical pumps, having a same size and/or rating. In some examples, one or more of the first pump 134 or the second pump 138 is a centrifugal pump. Other examples include other types of pumps, and numbers of pumps. For example, secondary closed loop 118 may in some examples include only a single pump, or may include more than two pumps. Overall, the first pump 134 and/or the second pump 138 may generate a flow rate of for example between 25 gallons per minute (GPM) and 200 GPM (e.g., 25 GPM, 50 GPM, 100 GPM, 125 GPM, 140 GPM, 160 GPM, or other values and ranges of values).

With continued reference to FIG. 1, in some examples the secondary closed loop 118 includes a refill tank 142 and a replenishing pump 146, for adding additional second fluid into the secondary closed loop 118. Additionally, in some examples the secondary closed loop 118 includes at least one expansion tank, for controlling an overall pressure and flow of the second fluid in the secondary closed loop 118. In the illustrated example, the secondary closed loop 118 includes a first expansion tank 150 and a second (e.g., redundant) expansion tank 154. Other examples may include just a single expansion tank, or more than two expansion tanks.

Additionally, both the primary closed loop 114 and the secondary closed loop 118 may include one or more valves (e.g., pressure control valves, check valves, pressure independent control valves, etc.) that operate to control the overall pressure and/or flow of fluid through the cooling distribution unit 110. In the illustrated example, the primary closed loop 114 includes a pressure independent control valve 158.

With continued reference to FIG. 1, in the illustrated example, the cooling distribution unit 110 includes a housing 162 (e.g., an outer housing). The housing 162 may include a steel frame (e.g., with interconnected vertical and/or horizontal frame members), or may be another type of frame, or be formed from different materials. In some examples, the housing 162 may include one or more doors (e.g., pivotally coupled or otherwise coupled to the frame). Other examples may include various other types, sizes, and/or shapes of housing 162 than that illustrated. In the illustrated example, the housing 162 includes a first outlet 166 where the primary closed loop 114 exits, and the first fluid is sent to the cooling structure 130. The housing 162 also includes a first inlet 170, where the primary closed loop 114 enters, and where the first fluid is then directed to the heat exchanger 126 (e.g., located within the housing 162). The housing 162 also includes a second outlet 174, where the secondary closed loop 118 exits and the second fluid is sent to the electrical components 122, and a second inlet 178, where the second fluid enters and is then directed to the heat exchanger 126.

With continued reference to FIG. 1, in some examples, the cooling distribution unit 110 additionally includes one or more sensors that measure pressure, temperature, or other aspects of the system. In the illustrated example, the cooling distribution unit 110 includes a plurality of pressure and temperature sensors (labeled as “PT” and “RTD” in FIG. 1) that are positioned generally at the first outlet 166, the first inlet 170, the second outlet 174, and the second inlet 178. As illustrated in FIG. 1, the cooling distribution unit 110 may include redundant pressure and temperature sensors (e.g., in the event one or more of the sensors fails or provide inaccurate readings).

In some examples, these sensors are coupled (e.g., wired or wirelessly) to a controller 182 (FIGS. 2-4) or other device that receives signals regarding the pressure and temperature of the first fluid and the second fluid. In the illustrated example, the controller 182 is located on and/or within the housing 162, and may include a user interface (e.g., graphical user interface, such as a color touchscreen). In some examples, the controller 182 is located remotely from the housing 162. In some examples, the controller 182 may be used to monitor pressure, monitor temperature, and/or control a flow and pressure differential of the second fluid.

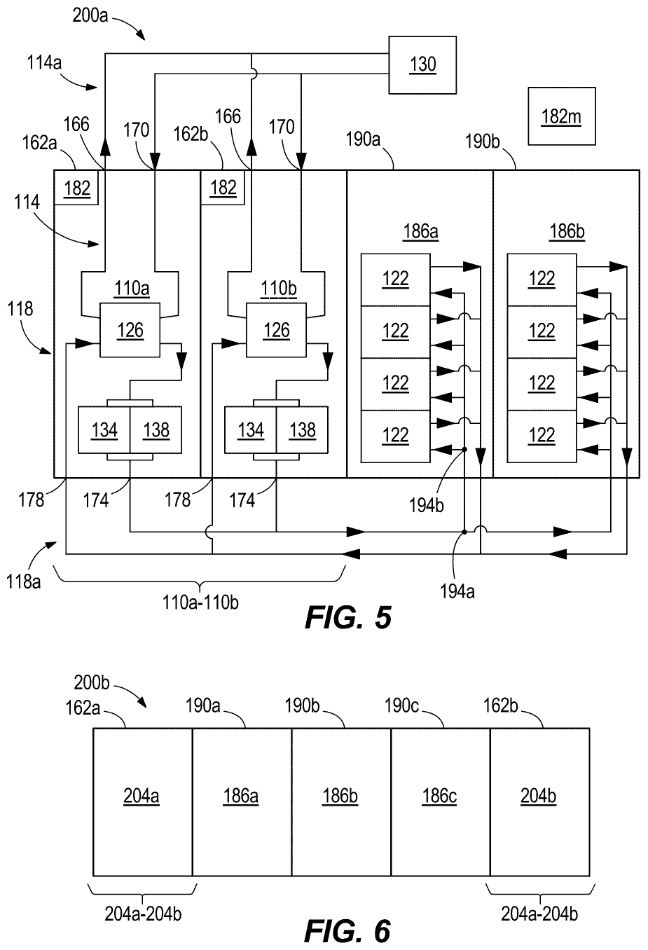

FIG. 5 illustrates a modular cooling distribution system 200a including an end-of-row cooling distribution unit group 110a-110b with a first cooling distribution unit 110a and an adjacent second cooling distribution unit 110b. In some examples, the first cooling distribution unit 110a is modularly coupleable to the second cooling distribution unit (110b). Each of the first cooling distribution unit 110a and the second cooling distribution unit 110b may include structural components and function in a similar manner to the cooling distribution unit 110 described above. For example, the cooling distribution units 110a, 110b each include heat exchangers 126, and a pump or multiple pumps 134, 138, each positioned within a corresponding housing 162a (i.e., a first housing), 162b (i.e., a second housing) as described above.

Each of the first cooling distribution unit 110a and the second cooling distribution unit 110b may include space to modularly receive a plurality of pumps 134, 138. In the illustrated example, each cooling distribution unit 110a, 110b includes two pumps 134, 138. However, additional pumps (i.e., a third pump, a fourth pump) may be connected in at least the first cooling distribution unit 110a. The third pump can be coupled in parallel with the first and second pumps 134, 138 to provide redundancy as described in detail below.

The modular cooling distribution system 200a further includes at least one electrical component group 186a within a housing 190a (i.e., a working housing, third housing) that is separate from and in-row with the first cooling distribution unit 110a and the second cooling distribution unit 110b. The modular cooling distribution system 200a of FIG. 5 illustrates both the electrical component group 186a and the housing 190a as well as another electrical component group 186b and another housing 190b (i.e., another working housing, fourth housing). Each electrical component group 186a, 186b includes at least one electrical component 122 to be cooled, and is positioned within the corresponding housing 190a, 190b. Typically, the electrical component groups 186a, 186b will include a plurality of electrical components 122. In the illustrated example, each housing 190a, 190b has a plurality of electrical components to be cooled stacked in a vertical direction in the housing 190a, 190b. In other examples, the electrical components 122 may be arranged in any manner within the housings 190a, 190b (e.g., a side-by-side or part stacked, part side-by-side arrangement, or the like).

As suggested by the ellipsis (“ . . . ”) in FIG. 5, the modular cooling distribution system 200a may be coupled to any number of additional electrical component groups (e.g., 186c, 186d, . . . , not shown). The additional electrical component groups, in some examples, may be physically located in the same row. It is also possible that the end-of-row cooling distribution group 110a-110b further be connected to a remote electrical component group (e.g., 186c) in a remote housing (e.g., 190c) at a remote location to the row that includes the end-of-row cooling distribution group 110a-110b. In some examples, the modular cooling distribution system 200a includes two cooling distribution units 110a, 110b that may serve between three and eight electrical component groups each in a corresponding housing (e.g., 190c, 190d, . . . , not shown). In some examples, a row includes between three and eight housings (or other numbers of housings) to be cooled by one or more cooling distribution units. The piping forming the primary closed loop 114 and secondary closed loop 118 can be modularly adjusted to provide necessary fluid couplings to the additional housings (e.g., 190c, 190d).

FIG. 5 further illustrates the primary closed loop 114 and secondary closed loop 118 as coupled to each of the first cooling distribution unit 110a and the adjacent second cooling distribution unit 110b. Fluid couplings may be made in any desired arrangement to fluidly couple the primary closed loop 114 and secondary closed loop 118 to the first cooling distribution unit 110a and the adjacent second cooling distribution unit 110b. For example, as shown in the illustrated secondary closed loop 118, the second outlets 174 of each cooling distribution unit 110a, 110b may be coupled to one another to form a system component cooling line 118a that extends to and returns from the electrical components 122 of both the housings 190a, 190b.

The primary closed loop 114 includes a cooling structure line 114a external to the housings 162a, 162b that provides fluid communication between the cooling structure 130 and the heat exchangers 126 of each cooling distribution unit 110a, 110b. In the illustrated example, the cooling structure line 114a includes branches to the first outlet 166 and the first inlet 170 of each cooling distribution unit 110a, 110b. Various piping arrangements for the cooling structure line 114a are possible. For example, valving may be provided to permit proportionally sending fluid of the primary closed loop 114 at desired flow rates to a cooling distribution unit 110a, 110b with high demand for flow of the first fluid (e.g., water). Similarly, the secondary closed loop 118 includes a component cooling line 118a external to the housings 162a, 162b that provides fluid communication between the electrical components 122 (i.e., collectively, the electrical component groups 186a, 186b in the housings 190a, 190b), and the heat exchangers 126 of each cooling distribution unit 110a, 110b. In the illustrated example, the component cooling line 118a includes branches to each second outlet 174 and second inlet 178 of each cooling distribution unit 110a, 110b. Various piping arrangements for the component cooling line 118a are possible.

FIG. 5 illustrates schematically the piping connections of the modular cooling distribution system 200a. In some examples, the first outlet 166 and first inlet 170 may be physically at a top of the housing 162a (e.g., to pass first fluid to a roof cooling structure 130 physically above the modular cooling distribution system 200a) and the second outlet 174 and the second inlet 178 may be physically at a bottom of the housing 162a (e.g., to pass second fluid to a subfloor or basement physically below the modular cooling distribution system 200a), but that need not be the case. Other arrangements are possible.

Optionally, one or more valves may be provided in the system component cooling line 118a to direct necessary proportions of fluid in the secondary cooling line to each of the housings 190a, 190b. For example, a three-way valve at intersection 194a may be provided to permit proportional adjustment of flow rate of secondary fluid to the housings 190a, 190b. As another option, one or more valves may be provided within one or more of the housings 190a, 190b to direct necessary proportions of fluid in the secondary cooling line to any individual electrical component 122 of the housing 190a, 190b. For example, a three-way valve at intersection 194b may be provided to permit proportional adjustment of flow rate of secondary fluid to each electrical component 122 of the housing 190a.

The modular cooling distribution system 200a may include a master controller 182m and/or may function with a controller of any of the cooling distribution units (i.e., the controller 182 of the first cooling distribution unit 110a) functioning as a master controller. The master controller 182m may be in electrical (e.g., wired or wireless) communication with the controllers 182 of each of the first cooling distribution unit 110a and the second cooling distribution unit 110b. The master controller 182m may be configured to calculate and/or predict a required amount of fluid flow to each housing 190a, 190b to provide and/or respond to cooling demand for the electrical components 122 thereof. The valve or valves at intersections 194a, 194b may be electrically coupled to the master controller 182m, or any controller 182 in the modular cooling distribution system 200a, for example, of the first cooling distribution unit 110a.

The master controller 182m or any controller 182 in the modular cooling distribution system 200a may be configured to calculate the necessary proportions of fluid flow in either or both of the primary closed loop 114 and the secondary closed loop 118 sent to the housings 190a, 190b and/or specific electrical components 122 within the housings 190a, 190b. The master controller 182m or any controller 182 in the modular cooling distribution system 200a may further be configured to drive and/or operate the first and second pumps 134, 138 of the cooling distribution group 110a-110b as a collective to provide necessary flow rate of the second fluid to counteract cooling demand of the electrical components 122. In some examples, the master controller 182m or any controller 182 may be configured to provide a signal to initiate actuation of and/or drive current to actuate the valve or valves at either of the intersections 194a, 194b or at any location in the modular cooling distribution system 200a to send appropriate proportions of second fluid to electrical components 122 that demand cooling. Additional locations of valves other than at the exact illustrated intersections 194a, 194b are also possible.

In some examples, the modular cooling distribution system 200a provides various pump redundancies and enhanced capability to provide higher flow rates to the electrical components 122. The first and second pumps 134, 138 of the same cooling distribution unit (e.g., 110a) may be redundant pumps. In some examples or operating situations, the first pump 134 and the second pump 138 may be oppositely working redundant pumps whereby when the first pump 134 is operated, the second pump 138 is not operated or vice versa. The operating pump may be alternated during the life of the cooling distribution unit 110a to inhibit unbalanced degradation of one pump faster than the other pump. In other examples or operating situations, the first pump 134 and the second pump 138 may be operable simultaneously to each provide motive force to the second fluid in the secondary closed loop 118. The modular cooling distribution system 200a enhances this capability by further permitting both pumps (or any number of pumps) of both cooling distribution units 110a, 110b (or any number of cooling distribution units 110a, 110b) to selectively contribute an amount of flow to the second fluid of the secondary closed loop 118.

The following illustrative example describes operation of the modular cooling distribution system 200a in an exemplary low demand situation, a medium demand situation, a high demand situation, and an extremely high demand situation. In the below-described example situations, each first and second pump 134, 138 of each cooling distribution unit 110a, 110b is capable of pumping at maximum capacity 100 gallons per minute (GPM) of second fluid in the secondary closed loop 118. The illustrative example may be scaled up or down to any sized modular cooling distribution system 200a.

In an exemplary low demand situation, each electrical component 122 of the electrical component group 186b is OFF; and the electrical component group 186a is ON and demands a level of cooling corresponding with a total of 80 GPM of second fluid flow. In this situation, the valve at intersection 194a may direct the second fluid toward the electrical component group 186a. Further, there are several options for the modular cooling distribution system 200a to provide the demanded second fluid flow for cooling. For example, both pumps 134, 138 of the second cooling distribution unit 110b and one pump (e.g., the second pump 138) of the first cooling distribution unit 110a may be OFF to conserve energy and inhibit degradation thereof; and one pump (e.g., the first pump 134) of the first cooling distribution unit may provide the demanded 80 GPM. As the first pump 134 of the first cooling distribution unit 110a is operated below its maximum capacity, efficiency gains may be realized. Alternately, two or more pumps 134, 138 may share the demand (e.g., 20 GPM, 20 GPM, 20 GPM, 20 GPM; 40 GPM, 0 GPM, 40 GPM, 0 GPM). Operation of the pumps 134, 138 and the exact proportionality of operation thereof may be automatically optimized by the master controller 182m. This arrangement also provides redundancies in that if the pump (e.g., the first pump 134) of the first cooling distribution unit 110a fails, any of the other pumps 134, 138 may be operated to provide the demanded 80 GPM.

In the event of a pump failure, the master controller 182m or any controller 182 may alert an operator to the failure, and the failed pump can be replaced with the remaining pumps of the system 134, 138, and the system may continue to pump the second fluid to address the cooling demand.

In an exemplary medium demand situation, each electrical component group 186a, 186b is ON and demands a level of cooling corresponding with 150 GPM of second fluid flow (e.g., a total of 300 GPM is demanded). In this situation, the valve at intersection 194a may be actuated to direct equal portions of the fluid flow to each electrical component group 186a, 186b. In a first option to respond to the 30 GPM demand, three of the four total pumps 134, 138 may be operated at maximum capacity. In a second option to respond to the 300 GPM demand, each of the four pumps 134, 138 may be operated simultaneously, with at least two pumps 134, 138 being operated at less than maximum capacity (e.g., 50 GPM, 50 GPM, 100 GPM, 100 GPM; 75 GPM, 75 GPM, 75 GPM, 75 GPM). Operation of the pumps 134, 138 and the exact proportionality of operation thereof may be automatically optimized by the master controller 182m. As at least one pump 134, 138 is either OFF or operated at less than maximum capacity, efficiency gains may be realized. This arrangement also provides redundancies in that if one of the four pumps 134, 138 fails, the 300 GPM demand can still be met by the three remaining pumps 134, 138.

In an exemplary high demand situation, the electrical component group 186a is ON and demands a level of cooling corresponding with 300 GPM of second fluid flow, and the electrical component group 186b is ON and demands a level of cooling corresponding with 50 GPM of second fluid flow. In this situation, the valve at intersection 194a may be actuated to direct 50 GPM of second fluid flow to the electrical component group 186b and 300 GPM of second fluid flow to the electrical component group 186a. Since the total demand second fluid flow of 350 GPM exceeds the maximum capacity of three pumps, all four pumps 134, 138 must be operated (e.g., 100 GPM, 100 GPM, 100 GPM, 50 GPM; 90 GPM, 90 GPM, 90 GPM, 80 GPM).

However, with this demand at least one pump is operated at less than maximum capacity, and efficiency gains may be realized. Operation of the pumps 134, 138 and the exact proportionality of operation thereof may be automatically optimized by the master controller 182m.

In a situation where additional electrical components 122 are added, are expected to demand additional cooling, or upon modularly coupling entirely new electrical component groups (e.g., 186c, 186d . . . , not shown) to the system, may advance cooling capacity requirements of the modular cooling distribution system 200a beyond that capable of being provided by the pumps 134, 138 of the first and second modular cooling distribution units 110a, 110b (e.g., to an extremely high demand). For example, if several new electrical component groups (e.g., 186c, 186d) are coupled to the first and second modular cooling distribution units 110a, 110b, typical (e.g., medium) cooling demand of the system may be shifted above the maximum capacity (e.g., above 400 GPM, to 500 GPM) provided by the four pumps 134, 138. In such a situation, prior to operation with the new electrical component groups (e.g., 186c, 186d) connected, a third cooling distribution unit 110c (not shown, also with two 100 GPM pumps) can be fluidly coupled in parallel to the existing cooling distribution group 110a-110b and to by branches the primary closed loop 114 and the secondary closed loop 118 to increase total cooling capacity of the resultant modular cooling distribution system 200a beyond that required. The third cooling distribution unit 110c may be physically positioned in the row at any desired location. In some examples, the third cooling distribution unit 110c is modularly coupleable to both the first cooling distribution unit 110a and the second cooling distribution unit 110b. In other examples, the third cooling distribution unit 110c may be physically separated from the same row as the first cooling distribution unit 110a and the second cooling distribution unit 110b.

FIG. 6 illustrates a modular cooling distribution system 200b including a first end-of-row cooling distribution unit 204a and an opposite second end-of-row second cooling distribution unit 204b, and three electrical component groups 186a-186c in three corresponding housings 190a-190c. The modular cooling distribution system 200b functions similarly to the modular cooling distribution system 200a and may share the same benefits described above. The primary closed loop 114, secondary closed loop 118, electrical components 122, heat exchangers 126, controllers 182, pumps 134, 138, and various inlets and outlets 166, 170, 174, 178 are not illustrated in FIG. 6 for simplicity's sake but are readily appreciable in view of the description to the modular cooling distribution system 200a (FIG. 5). While the first cooling distribution unit 204a and second cooling distribution unit 204b are physically separated from one another, by connection of the fluid lines providing at least the secondary closed loop 118, the modular cooling distribution system 200b can provide a cooling distribution group 204a-204b whereby both the first cooling distribution units 204a and the second cooling distribution unit 204b are configured to contribute to a total flow demand of secondary fluid flow.

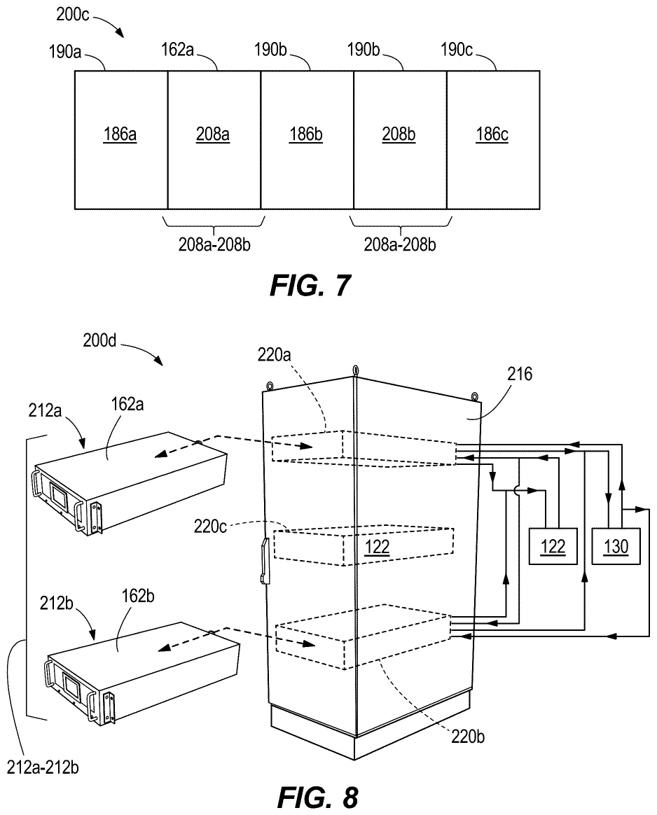

FIG. 7 illustrates a modular cooling distribution system 200c including a first cooling distribution unit 208a and a second cooling distribution unit 208b forming a cooling distribution group 208a-208b interspersed between electrical component groups 186a-186c and corresponding housings 190a-190c. In other words, the cooling distribution system 200c alternates along the row between electrical component group and cooling distribution unit. In the illustrated example, an alternating pattern of an electrical component group and subsequently a cooling distribution unit is present along the row. While the first cooling distribution unit 208a and second cooling distribution unit 208b are physically separated from one another, by connection of the fluid lines providing at least the secondary closed loop 118, the modular cooling distribution system 200c can provide a cooling distribution group 208a-208b whereby both the first cooling distribution units 208a and the second cooling distribution unit 208b are configured to contribute to a total flow demand of secondary fluid flow. Various repeating or non-repeating patterns are possible. In other examples, the arrangement of electrical component groups 186a-186c and cooling distribution units 208a, 208b need not be an alternating pattern. For example, two or more electrical component groups 186a-186c may be present between cooling distribution units 208a, 208b. Alternately, in some examples, two cooling distribution units 208a, 208b may be physically positioned adjacent to one another in the row. The modular cooling distribution system 200a-200c may be modularly reconfigurable within the data center to a desired configuration.

Selection of an arrangement of an in-row modular cooling distribution system 200a-200c may depend on the data center space in which the modular cooling distribution system 200a-200c is positioned, or for any other reason.

FIG. 8 illustrates a modular cooling distribution system 200d including a first cooling distribution unit 212a and a second cooling distribution unit 212b each positioned within a corresponding housing 162a, 162b and each received by a common housing 216. The housings 162a, 162b of the first cooling distribution unit 212a and the second cooling distribution unit 212b are effectively sub-housings to the housing 216, and are sized to fit within corresponding receptacles 220a, 220b of the housing 216. The first cooling distribution unit 212a and second cooling distribution unit 212b may be stacked due to a stacked spatial relationship of the receptacles 220a, 220b. The electrical component 122 illustrated in FIG. 8 is exterior to the housing 216, and may be positioned within a housing (e.g., housing 190a) adjacent the housing 216 or remote to the housing 216. More than two cooling distribution units 212a, 212b may be provided in the same housing 216. Further, optionally, one or more electrical components 122 to be cooled may be positioned within the same housing 216 as the first cooling distribution unit 212a and the second cooling distribution unit 212b. The electrical component 122 may be sized to engage a receptacle 220c. In some examples, the receptacles 220a, 220b configured to receive the cooling distribution units 212a, 212b may be sized the same as the receptacles 220c configured to receive the electrical components 122. FIG. 8 illustrates the receptacle 220c stacked between the receptacles 220a, 220b. However, other arrangements are possible, such as side-by-side receptacles adjacent one another within the housing 216 at the same height in the housing 216. While the first cooling distribution unit 212a and second cooling distribution unit 212b are physically separated from one another, by connection of the fluid lines providing at least the secondary closed loop 118, the modular cooling distribution system 200d can provide a cooling distribution group 212a-212b whereby both the first cooling distribution units 212a and the second cooling distribution unit 212b are configured to contribute to a total flow demand of secondary fluid flow.

The cooling distribution group 212a-212b can be coupled to an existing cooling distribution group (e.g., the cooling distribution group 110a-110b) to provide a hybrid type modular cooling distribution system with both modular in-row cooling distribution units (e.g., 110a, 110b) and modular in-rack cooling distribution units (e.g., 212a, 212b). Arrangement of the housing 216 or any number of housings 216 in the hybrid type modular cooling distribution system may vary.

As a data center changes in computational capacity, the modular cooling distribution system 200a-200d can be adjusted by adding, removing, or replacing either an in-row CDU (such as 110a) or by adding, removing, or replacing an in-rack CDU (such as 212a) such that the cooling distribution system 200a-200d has an appropriate cooling and/or pumping capacity. By providing modular connections to easily couple and rearrange the cooling distribution system, design cycle (i.e., time to redesign the system) is reduced, system cost including both the up-front cost of the system, cost of modifying the system based on a change in cooling demand, and the operating cost of the system is improved. Due to modularity and ability to connect for example, additional or fewer or different capacity pumps 134, 138, and/or additional or fewer or different capacity in-row CDUs (e.g., 110a, 110b) and/or additional or fewer or different capacity in-rack CDUs (e.g., 212a, 212b), modular cooling distribution system 200a-200d can effectively provide a flexible design with modular standard “building block” components where components can be interchanged for one another (or for an electrical component 122 to be cooled).

In the illustrated example, the cooling distribution unit 110 has an overall dimension of 31.5″ by 47.4″ by 84.5″, and an overall weight of approximately 1400 pounds. Other examples may include different sizes and weights, including sizes smaller and larger than that illustrated, and weights smaller or greater than that illustrated. Additionally, in the illustrated example, the cooling distribution unit 110 may provide a cooling capacity of 550 kW (at 4° C. approach temperature difference) and 1100 kW (at 8° C. approach temperature difference). Other examples may include other values and ranges of values of cooling capacity, including a cooling capacity smaller or greater than that illustrated.

In some examples, a single cooling distribution unit 212a (e.g., of the modular cooling distribution system 200d) has an overall dimension of approximately 38″ by 17.7″ by 6.9″, and an overall weight of approximately 135 pounds. Other examples may include different sizes and weights, including sizes smaller and larger than that illustrated, and weights smaller or greater than that illustrated. Additionally, in the illustrated example, a single cooling distribution unit 212a may provide a cooling capacity of 80 kW (at 9.5° C. approach temperature difference). The cooling distribution unit 212a may have an operating flowrate range of its portion of the secondary closed loop 118 of between approximately 2.64 gallons per minute and 26.4 gallons per minute. Other examples may include other values and ranges of values of cooling capacity, including a cooling capacity smaller or greater than that illustrated.

Although various aspects and examples have been described in detail with reference to certain examples illustrated in the drawings, variations and modifications exist within the scope and spirit of one or more independent aspects described and illustrated.

What is claimed is:

1. A modular cooling distribution system comprising:
a first cooling distribution unit including a first heat exchanger and a first pump positioned within a first housing;
a second cooling distribution unit including a second heat exchanger and a second pump positioned within a second housing;
a component to be cooled positioned within a third housing;
a primary closed loop in fluid communication with the first heat exchanger, the second heat exchanger, and an external cooling structure; and
a secondary closed loop in fluid communication with the first heat exchanger, the second heat exchanger, and the component to be cooled;
wherein the first cooling distribution unit and the second cooling distribution unit are modularly coupleable to one another and modularly operable as a cooling distribution unit group whereby either or both of the first pump and the second pump are configured to drive fluid in the secondary closed loop to pass heat of the component to the secondary closed loop, the primary closed loop, and the external cooling structure.

2. The modular cooling distribution system of claim 1, wherein the first housing and the second housing arranged side-by-side in a row.

3. The modular cooling distribution system of claim 2, wherein the first housing, the second housing, and the third housing are arranged side-by-side in a row.

4. The modular cooling distribution system of claim 3, further comprising a second component to be cooled positioned within a fourth housing arranged side-by-side with the third housing in the row.

5. The modular cooling distribution system of claim 1, wherein the first housing, the second housing, and the third housing are each arranged side-by-side in a row with the third housing between the first housing and the second housing.

6. The modular cooling distribution system of claim 5, further comprising a second component to be cooled positioned within a fourth housing arranged side-by-side in the row between the third housing and the fourth housing.

7. The modular cooling distribution system of claim 5, further comprising a second component to be cooled positioned within a fourth housing arranged side-by-side in the row adjacent the second housing and separated from the third housing by the second housing.

8. The modular cooling distribution system of claim 1, further comprising a plurality of components to be cooled in the third housing, the plurality of components to be cooled in fluid communication with the secondary closed loop.

9. The modular cooling distribution system of claim 1, further including a piping arrangement to couple the primary closed loop to both the first cooling distribution unit and the second cooling distribution unit and the secondary closed loop to both the first cooling distribution unit and the second cooling distribution unit.

10. The modular cooling distribution system of claim 1, further comprising a third cooling distribution unit modularly coupleable to the first cooling distribution unit and the second cooling distribution unit.

11. The modular cooling distribution system of claim 1, wherein the first pump and the second pump are operable simultaneously to each provide motive force to fluid in the secondary closed loop.

12. The modular cooling distribution system of claim 1, wherein the first pump and the second pump are configured to function as oppositely working redundant pumps, whereby when the first pump is operated, the second pump is not operated or vice versa.

13. The modular cooling distribution system of claim 1, further comprising at least one controller configured to drive the first pump and/or the second pump at an appropriate level to respond to cooling demand of the component.

14. A modular cooling distribution system comprising:
a housing including a first receptacle configured to removably receive a first sub-housing and a second receptacle configured to removably receive a second sub-housing;
a first cooling distribution unit including a first heat exchanger and a first pump, the first cooling distribution unit positioned within the first sub-housing;
a second cooling distribution unit including a second heat exchanger and a second pump, the second cooling distribution unit positioned with the second sub-housing;
a component to be cooled;
a primary closed loop in fluid communication with the first heat exchanger, the second heat exchanger, and an external cooling structure; and
a secondary closed loop in fluid communication with the first heat exchanger, the second heat exchanger, and the component to be cooled.

15. The modular cooling distribution system of claim 14, wherein the first sub-housing and the second sub-housing are stacked in the housing.

16. The modular cooling distribution system of claim 14, wherein the component to be cooled is positioned within the housing.

17. The modular cooling distribution system of claim 16, wherein the component to be cooled is stacked above or below either of the first sub-housing and the second sub-housing within the housing.

18. A modular cooling distribution system comprising:
a row of a plurality of housings each including a plurality of racks with an electrical component to be cooled;
a first cooling distribution unit including a first heat exchanger and a first pump;
a second cooling distribution unit including a second heat exchanger and a second pump;
a primary closed loop in fluid communication with the first heat exchanger, the second heat exchanger, and an external cooling structure; and
a secondary closed loop in fluid communication with the first heat exchanger, the second heat exchanger, and the plurality of electrical components to be cooled;
wherein the first cooling distribution unit and the second cooling distribution unit are modularly coupled to the primary closed loop and the secondary closed loop so to be rearrangeable in the row or to a receptacle in at least one of the plurality of racks.

19. The modular cooling distribution system of claim 18, further comprising a third cooling distribution unit including a third heat exchanger and a third pump, wherein the third cooling distribution unit is modularly coupled to the primary closed loop and the secondary closed loop so to be arranged in the row or to the receptacle at a desired location.

20. The modular cooling distribution system of claim 18, wherein the row includes between three and eight housings to be cooled by the first cooling distribution unit and the second cooling distribution unit.
